(19) United States
(12) Patent Application Publication
(10) Pub. No.: US 2026/0018930 A1
(43) Pub. Date: Jan. 15, 2026

(54) wireless charging printed circuit board

(71) Applicant: CYNTEC CO., LTD., Hsinchu (TW)

(72) Inventors: Yen-Ming Liu, Hsinchu (TW); Chih-Hung Wei, Hsinchu (TW); Yun-Ching Lai, Hsinchu (TW)

(73) Assignee: CYNTEC CO., LTD., Hsinchu (TW)

(21) Appl. No.: 19/260,327

(22) Filed: Jul. 4, 2025

Related U.S. Application Data
(60) Provisional application No. 63/668,779, filed on Jul. 9, 2024.

(51) Int. Cl. H02J 50/10; H01F 27/28; H02J 50/00; H05K 1/11

(52) U.S. Cl. CPC H02J 50/10; H01F 27/2804; H02J 50/005; H05K 1/115

(57) ABSTRACT

The present disclosure provides a multi-function charging printed circuit board by forming a short-range antenna and multiple charging coils on multiple layers, wherein the short-range antenna and at least one charging coil is integrated on a single layer. One or more temperature-detecting units are disposed on the charging side of the charging printed circuit board for effectively dissipating heat and avoiding over-temperature accidents. A ferrite sheet is attached to the bottom side of the wireless charging printed circuit board for improving the efficiency of wireless charging.

### CROSS REFERENCE TO RELATED APPLICATIONS

This application claims the benefit of U.S. Provisional Application No. 63/668,779, filed on Jul. 9, 2024. The content of the application is incorporated herein by reference.

### BACKGROUND OF THE INVENTION

### 1. Field of the Invention

The present invention is related to a wireless charging printed circuit board, and more particularly, to a wireless charging printed circuit board which integrates an NFC antenna and a charging coil on the same layer.

### 2. Description of the Related Art

The main way of charging electronic devices at present is based on traditional wired charging technology, wherein power transmission is realized by the physical connection of plug and socket. However, it also has a variety of problems, such as safety concerns caused by abrasion and aging, the inconvenience of charging portable electronic equipment and implantable medical equipment, and the danger of power transmission in hazardous working environments.

With development of intelligent technologies and the expansion of electric vehicle market, wireless charging technology is expected to become the mainstream due its excellent features such as high charging convenience, no need of manual intervention/attendance, low maintenance costs, a small footprint, low electric leakage risk, and dynamic charging during movement.

Wireless charging refers to a process in which a device that is charged based on an electromagnetic wave induction principle. The principle is similar to that of a transformer. There is a coil at a transmit terminal and a coil at a receive terminal. The coil at the transmit terminal is connected to a wired power supply and generates an electromagnetic signal. The coil at the receive terminal induces the electromagnetic signal from the transmit terminal and converts the electromagnetic signal into a required direct current, to charge a battery at the receive terminal. In order to achieve maximum charging efficiency, it needs to be ensured that an electronic device to be charged is located right above the chargeable area (active area) of a wireless charging board. This can be tricky in automotive application wherein the wireless charging process is often performed in motion, thereby causing location misalignment.

The Qi standard launched by the Wireless Power Consortium (WPC) unifies the wireless charging industry under one global standard, eliminating consumer confusion and enabling greater device interoperability. By combining Qi wireless charging and near-field communication (NFC) technology, a user can put his phone onto the wireless charger and establish connectivity to exchange data via NFC while charging the phone. However, the thickness of the NFC board in a traditional wireless charger increases the distance between the coil at a transmit terminal and the coil at a receive terminal, thereby lowering charging efficiency.

Therefore, there is a need for a wireless charging module that can increase the chargeable area (active area) and heat dissipation effect during high wattage charging.

### SUMMARY OF THE INVENTION

The present invention provides a wireless charging printed circuit board which includes a charging side, a bottom side, a plurality of layers arranged between the charging side and the bottom side, an electric field shielding mechanism implemented on a first layer among the plurality of layers, an antenna pattern and a first coil pattern formed on a second layer among the plurality of layers, a second coil pattern formed on a third layer among the plurality of layers, and a ferrite sheet attached to the bottom side of the wireless charging printed circuit board. The first coil pattern is arranged on a central region of the second layer, and the antenna pattern is arranged on a peripheral region of the second layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a wireless charging printed circuit board according to an embodiment of the present disclosure.

FIG. 2 is a schematic diagram illustrating a wireless charging printed circuit board according to another embodiment of the present disclosure.

FIG. 3A is a schematic diagram illustrating an implementation of a wireless charging printed circuit board which adopts a single primary charging coil and a single auxiliary charging coil according to an embodiment of the present disclosure.

FIG. 3B is a schematic diagram illustrating an implementation of a wireless charging printed circuit board which adopts a single primary charging coil and a single auxiliary charging coil according to an embodiment of the present disclosure.

FIG. 4A is a schematic diagram illustrating an implementation of a wireless charging printed circuit board which adopts a single primary charging coil and multiple auxiliary charging coils according to an embodiment of the present disclosure.

FIG. 4B is a schematic diagram illustrating an implementation of a wireless charging printed circuit board which adopts a single primary charging coil and multiple auxiliary charging coils according to an embodiment of the present disclosure.

FIG. 5A is a schematic diagram illustrating an implementation of a wireless charging printed circuit board which adopts a single primary charging coil and a single auxiliary charging coil in a stacked configuration according to an embodiment of the present disclosure.

FIG. 5B is a schematic diagram illustrating an implementation of a wireless charging printed circuit board which adopts a single primary charging coil and a single auxiliary charging coil in a stacked configuration according to an embodiment of the present disclosure.

FIG. 6A is a schematic diagram illustrating an implementation of a wireless charging printed circuit board which adopts multiple primary charging coils or multiple auxiliary charging coils in a stacked configuration according to an embodiment of the present disclosure.

FIG. 6B is a schematic diagram illustrating an implementation of a wireless charging printed circuit board which adopts multiple primary charging coils or multiple auxiliary charging coils in a stacked configuration according to an embodiment of the present disclosure.

FIG. 7A is a schematic diagram illustrating an implementation of a wireless charging printed circuit board which adopts multiple primary charging coils and multiple auxiliary charging coils in a stacked configuration according to an embodiment of the present disclosure.

FIG. 7B is a schematic diagram illustrating an implementation of a wireless charging printed circuit board which adopts multiple primary charging coils and multiple auxiliary charging coils in a stacked configuration according to an embodiment of the present disclosure.

FIG. 8A is a top-view schematic diagram illustrating a wireless charging printed circuit board according to an embodiment of the present disclosure.

FIG. 8B is a top-view schematic diagram illustrating a wireless charging printed circuit board according to an embodiment of the present disclosure.

FIG. 8C is a top-view schematic diagram illustrating a wireless charging printed circuit board according to an embodiment of the present disclosure.

FIG. 8D is a top-view schematic diagram illustrating a wireless charging printed circuit board according to an embodiment of the present disclosure.

FIG. 8E is a top-view schematic diagram illustrating a wireless charging printed circuit board according to an embodiment of the present disclosure.

FIG. 8F is a top-view schematic diagram illustrating a wireless charging printed circuit board according to an embodiment of the present disclosure.

### DETAILED DESCRIPTION

The present disclosure provides a detailed description of various embodiments. While specific implementation details are presented herein to facilitate a comprehensive understanding of the disclosure, it will be apparent to those skilled in the art that the present invention may be realized without necessarily adhering to all such particularities. In certain instances, well-established methods, procedures, components, and circuits have been omitted from exhaustive description to avoid obscuring the present disclosure. It should be understood that technical features individually described in relation to a single drawing may be implemented either discretely or in combination with other features, as set forth in the present specification.

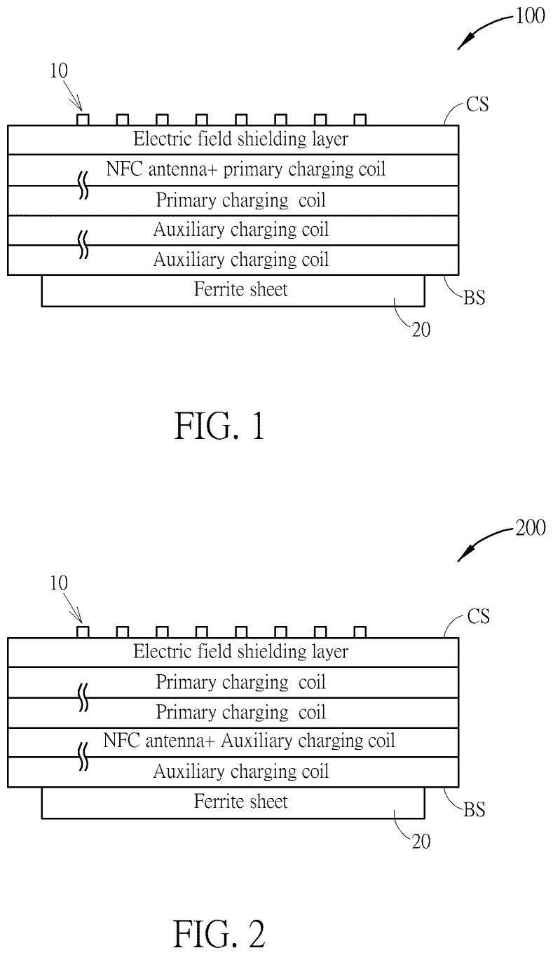

FIG. 1 is a schematic diagram illustrating a wireless charging printed circuit board 100 according to an embodiment of the present disclosure. FIG. 2 is a schematic diagram illustrating a wireless charging printed circuit board 200 according to another embodiment of the present disclosure. Each of the charging printed circuit boards 100 and 200 includes a plurality of layers stacked between a charging side CS and a bottom side BS for accommodating an electric field shielding layer, a short-range antenna, one or more primary charging coils, and one or more auxiliary charging coil. In an embodiment, the short-range antenna may be an NFC antenna capable of establishing connectivity to exchange data during the wireless charging process. However, the type of the short-range antenna does not limit the scope of the present disclosure.

In the present disclosure, one or more temperature-detecting units 10 may be disposed on the charging side CS of the charging printed circuit boards 100 and 200 for effectively dissipating heat and avoiding over-temperature accidents. In an embodiment, each temperature-detecting unit may be a negative temperature coefficient (NTC) thermistor configured to track the instantaneous temperature change of the charging printed circuit boards 100 and 200, thereby ensuring the safety of the wireless charging process. However, the type of the temperature-detecting units 10 does not limit the scope of the present disclosure.

In the present disclosure, a ferrite sheet 20 may be attached to the bottom side BS of the wireless charging printed circuit boards 100 and 200. The ferrite sheet 20 may improve the efficiency of wireless charging by guiding the electromagnetic field generated by a transmitter coil and directing it toward the receiver coil, which maximizes direct energy transfer. In an embodiment, the ferrite sheet 20 may adopt metal oxide with ferromagnetic properties. As far as electrical properties are concerned, the resistivity of the ferrite sheet 20 is much larger than that of metal and alloy magnetic materials, and it also has high dielectric properties and features a high relative permeability at high frequencies, thereby capable of minimizing leakage, suppressing noises and reducing electromagnetic interference (EMI) during the wireless charging process. However, the type of the ferrite sheet 20 does not limit the scope of the present disclosure.

In the wireless charging printed circuit board 100 depicted in FIG. 1, an electric field shielding mechanism is implemented on the topmost layer among the plurality of layers for forming the electric field shielding layer. One or more primary charging coils are formed on subsequent one or more layers below the electric field shielding layer, wherein the short-range antenna and at least one primary charging coil are formed on the layer directly below the electric field shielding layer. One or more auxiliary charging coils are formed on one or more bottom layers among the plurality of layers.

In the wireless charging printed circuit board 200 depicted in FIG. 2, an electric field shielding mechanism is implemented on the topmost layer among the plurality of layers for forming the electric field shielding layer. One or more primary charging coils are formed on subsequent one or more layers below the electric field shielding layer. One or more auxiliary charging coils are formed on one or more bottom layers among the plurality of layers, wherein the short-distance antenna and at least one auxiliary charging coil are formed on the top-most layer among the one or more bottom layers.

In the present disclosure, a primary charging coil refers to a more frequently used coil and an auxiliary coil refers to a less frequently used coil with normal disposition of phones. In the wireless charging printed circuit boards 100 and 200, each primary charging coil is formed on a higher layer at a central region, while each auxiliary charging coil is formed on a lower layer at a lateral region for improving the efficiency of wireless charging process.

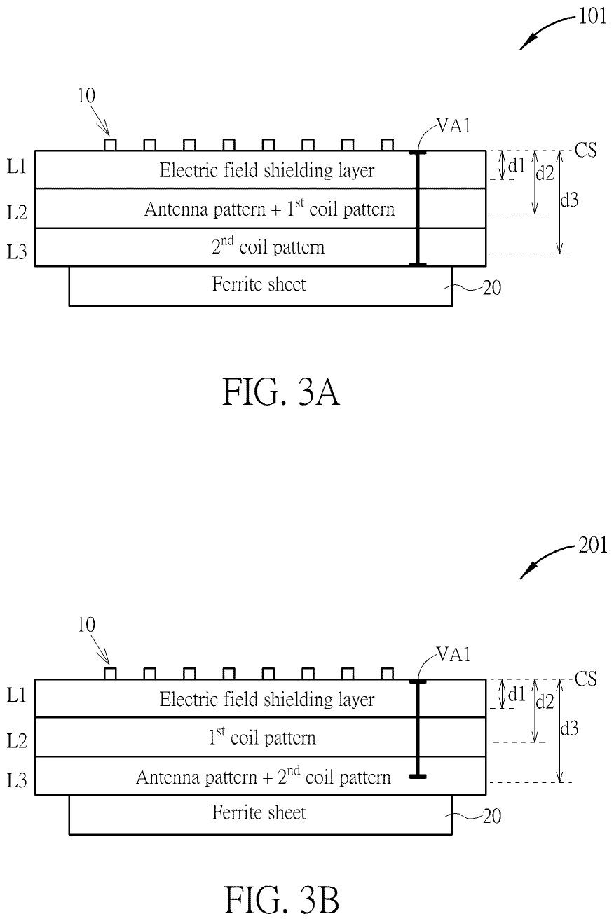

FIGS. 3A and 3B are schematic diagrams illustrating the implementation of the wireless charging printed circuit boards 100 and 200 which adopt a single primary charging coil and a single auxiliary charging coil according to embodiments of the present disclosure. FIG. 3A is a schematic diagram illustrating a wireless charging printed circuit board 101 implemented based on the wireless charging printed circuit board 100 depicted in FIG. 1. FIG. 3B is a schematic diagram illustrating a wireless charging printed circuit board 201 implemented based on the wireless charging printed circuit board 200 depicted in FIG. 2.

In the wireless charging printed circuit board 101 depicted in FIG. 3A, an electric field shielding mechanism is implemented on a first layer L1 among the plurality of layers for forming the electric field shielding layer. An antenna pattern and a first coil pattern are formed on a second layer L2 among the plurality of layers. A second coil pattern is formed on a third layer L3 among the plurality of layers. As depicted in FIG. 3A, d1-d3 represent the distances between the layers L1-L3 and the charging side CS, respectively, wherein d1<d2<d3. The first coil pattern on the second layer L2 forms a primary charging coil, and the second coil pattern on the third layer L3 forms an auxiliary charging coil. Also, the wireless charging printed circuit board 101 may further include a via VA1 (such as a through via depicted in FIG. 3A or a blind via depicted in FIG. 3B) which passes through the layers L1-L3 for reducing the direct current resistance (DCR) of the charging coils.

In the wireless charging printed circuit board 201 depicted in FIG. 3B, an electric field shielding mechanism is implemented on a first layer L1 among the plurality of layers for forming the electric field shielding layer. A first coil pattern is formed on a second layer L2 among the plurality of layers. An antenna pattern and a second coil pattern are formed on a third layer L3 among the plurality of layers. As depicted in FIG. 3B, d1-d3 represent the distances between the layers L1-L3 and the charging side CS, respectively, wherein d1<d2<d3. The first coil pattern on the second layer L2 forms a primary charging coil, and the second coil pattern on the third layer L3 forms an auxiliary charging coil. Also, the wireless charging printed circuit board 201 may further include a via VA1 (such as a through via depicted in FIG. 3A or a blind via depicted in FIG. 3B) which passes through the layers L1-L3 for reducing the DCR of the charging coils.

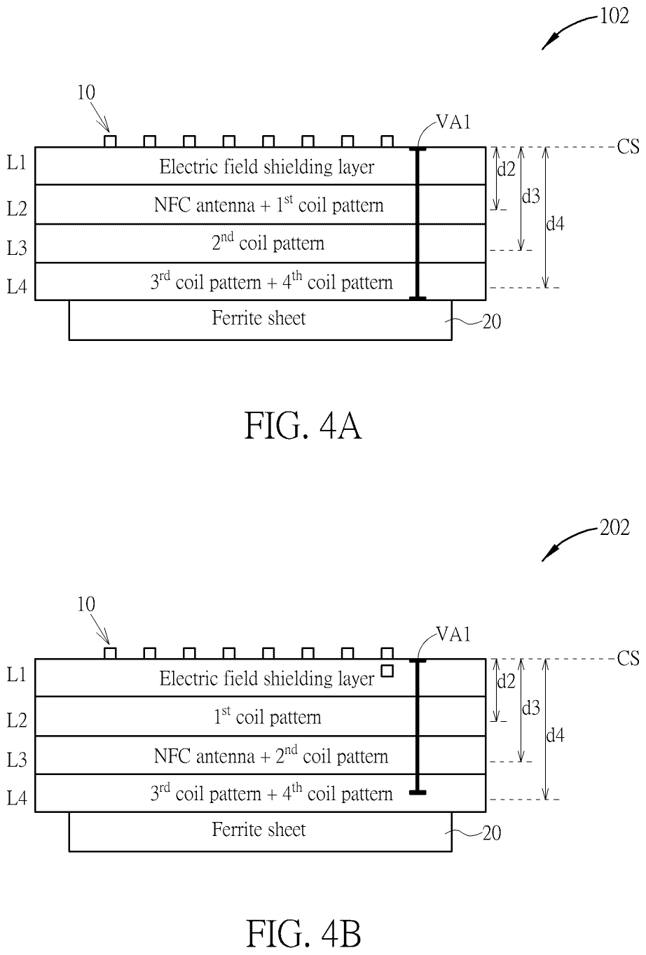

FIGS. 4A and 4B are schematic diagrams illustrating the implementation of the wireless charging printed circuit boards 100 and 200 which adopt a single primary charging coil and multiple auxiliary charging coils according to embodiments of the present disclosure. FIG. 4A is a schematic diagram illustrating a wireless charging printed circuit board 102 implemented based on the wireless charging printed circuit board 100 depicted in FIG. 1. FIG. 4B is schematic a diagram illustrating a wireless charging printed circuit board 202 implemented based on the wireless charging printed circuit board 200 depicted in FIG. 2.

In the wireless charging printed circuit board 102 depicted in FIG. 4A, an electric field shielding mechanism is implemented on a first layer L1 among the plurality of layers for forming the electric field shielding layer. An antenna pattern and a first coil pattern are formed on a second layer L2 among the plurality of layers. A second coil pattern is formed on a third layer L3 among the plurality of layers. A third coil pattern and a fourth coil pattern are formed on a fourth layer L4 among the plurality of layers. As depicted in FIG. 4A, d2-d4 represent the distances between the layers L2-L4 and the charging side CS, respectively, wherein d2<d3<d4. The first coil pattern on the second layer L2 forms a primary charging coil, the second coil pattern on the third layer L3 forms a first auxiliary charging coil, the third coil pattern on the fourth layer L4 forms a second auxiliary charging coil, and the fourth coil pattern on the fourth layer L4 forms a third auxiliary charging coil. Also, the wireless charging printed circuit board 102 may further includes a via VA1 (such as a through via depicted in FIG. 4A or a blind via depicted in FIG. 4B) which passes through the layers L1-L4 for reducing the DCR of the charging coils.

In the wireless charging printed circuit board 202 depicted in FIG. 4B, an electric field shielding mechanism is implemented on a first layer L1 among the plurality of layers for forming the electric field shielding layer. A first coil pattern is formed on a second layer L2 among the plurality of layers. An antenna pattern and a second coil pattern are formed on a third layer L3 among the plurality of layers. A third coil pattern and a fourth pattern are formed on a fourth layer L4 among the plurality of layers. As depicted in FIG. 4B, d2-d4 represent the distances between the layers L2-L4 and the charging side CS, respectively, wherein d2<d3<d4. The first coil pattern on the second layer L2 forms a primary charging coil, the second coil pattern on the third layer L3 forms a first auxiliary charging coil, the third coil pattern on the fourth layer L4 forms a second auxiliary charging coil, and the fourth coil pattern on the fourth layer L4 forms a third auxiliary charging coil. Also, the wireless charging printed circuit board 202 may further include a via VAL (such as a through via depicted in FIG. 4A or a blind via depicted in FIG. 4B) which passes through the layers L1-L4 for reducing the DCR of the charging coils.

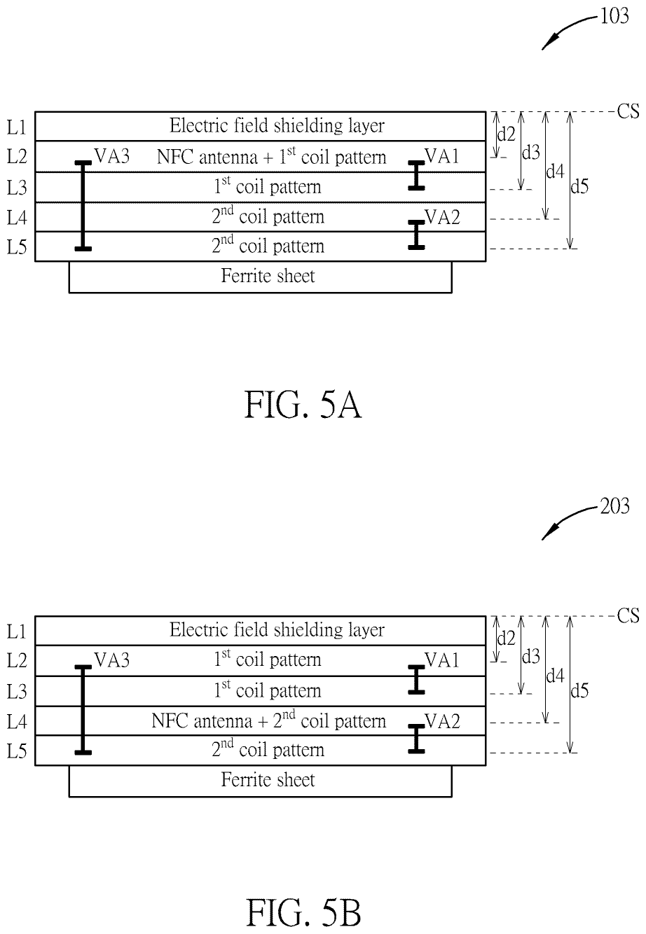

FIGS. 5A and 5B are schematic diagrams illustrating the implementation of the wireless charging printed circuit boards 100 and 200 which adopt a single primary charging coil and a single auxiliary charging coil in a stacked configuration according to embodiments of the present disclosure. FIG. 5A is a schematic diagram illustrating a wireless charging printed circuit board 103 implemented based on the wireless charging printed circuit board 100 depicted in FIG. 1. FIG. 5B is a schematic diagram illustrating a wireless charging printed circuit board 203 implemented based on the wireless charging printed circuit board 200 depicted in FIG. 2.

In the wireless charging printed circuit board 103 depicted in FIG. 5A, an electric field shielding mechanism is implemented on a first layer L1 among the plurality of layers for forming the electric field shielding layer. An antenna pattern and a first coil pattern are formed on a second layer L2 among the plurality of layers, while the first coil pattern is also formed on a third layer L3 among the plurality of layers. A second coil pattern is formed on a fourth layer L4 and a fifth layer L5 among the plurality of layers. As depicted in FIG. 5A, d2-d5 represent the distances between the layers L2-L5 and the charging side CS, respectively, wherein d2<d3<d4<d5. Also, the wireless charging printed circuit board 103 further includes a via VA1 (such as a buried via) which passes through the layers L2-L3 and a via VA2 (such as a buried via) which passes through the layers L4-L5 for providing flexible electrical connections between layers, and may further include a via VA3 (such as a buried via) which passes through the layers L2-L5 for reducing the DCR of the charging coils. Although not shown in FIG. 5A, the wireless charging printed circuit board 103 may also include a through via or a blind via for further reducing the DCR of the charging coils. The first coil patterns on the second layer L2 and the third layer L3 coupled in parallel by the via VA1 form a primary charging coil, and the second coil patterns on the fourth layer L4 and the fifth layer L5 coupled in parallel by the via VA2 form an auxiliary charging coil.

In the wireless charging printed circuit board 203 depicted in FIG. 5B, an electric field shielding mechanism is implemented on a first layer L1 among the plurality of layers for forming the electric field shielding layer. A first coil pattern is formed on a second layer L2 and a third layer L3 among the plurality of layers. An antenna pattern and a second coil pattern is formed on a fourth layer L4 among the plurality of layers, while the second coil pattern is also formed on a fifth layer L5 among the plurality of layers. As depicted in FIG. 5B, d2-d5 represent the distances between the layers L2-L5 and the charging side CS, respectively, wherein d2<d3<d4<d5. Also, the wireless charging printed circuit board 203 further includes a via VA1 (such as a buried via) which passes through the layers L2-L3 and a via VA2 (such as a buried via) which passes through the layers L4-L5 for providing flexible electrical connections between layers, and may further include a via VA3 (such as a buried via) which passes through the layers L2-L5 for reducing the DCR of the charging coils. Although not shown in FIG. 5B, the wireless charging printed circuit board 203 may also include a through via or a blind via for further reducing the DCR of the charging coils. The first coil patterns on the second layer L2 and the third layer L3 coupled in parallel by the via VA1 form a primary charging coil. The second coil patterns on the fourth layer L4 and the fifth layer L5 coupled in parallel by the via VA2 and form an auxiliary charging coil.

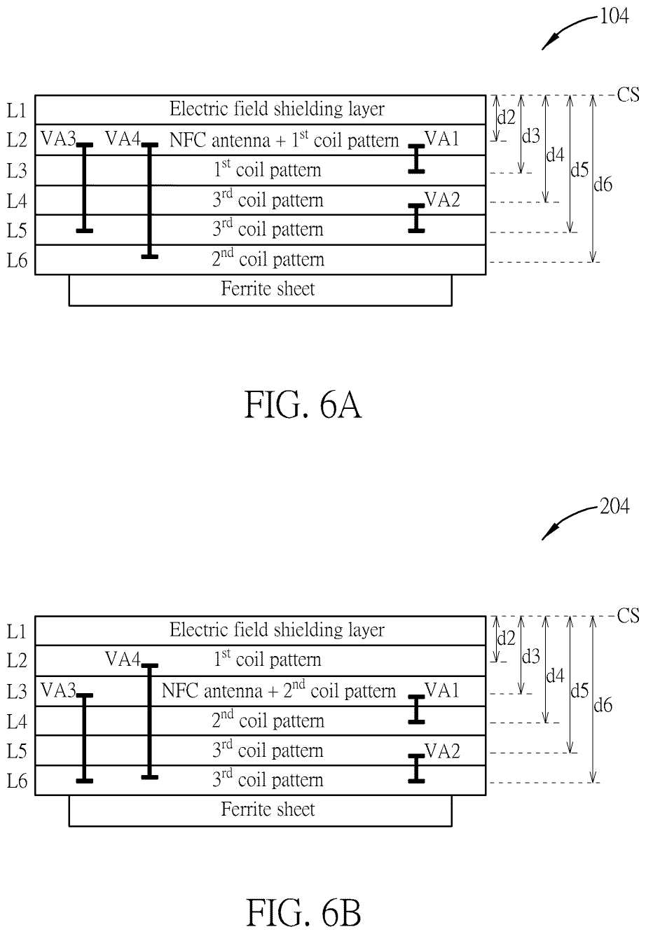

FIGS. 6A and 6B are schematic diagrams illustrating the implementation of the wireless charging printed circuit boards 100 and 200 which adopt multiple primary coils or multiple auxiliary coils in a stacked configuration according to embodiments of the present disclosure. FIG. 6A is a schematic diagram illustrating a wireless charging printed circuit board 104 implemented based on the wireless charging printed circuit board 100 depicted in FIG. 1. FIG. 6B is a schematic diagram illustrating a wireless charging printed circuit board 204 implemented based on the wireless charging printed circuit board 200 depicted in FIG. 2.

In the wireless charging printed circuit board 104 depicted in FIG. 6A, an electric field shielding mechanism is implemented on a first layer L1 among the plurality of layers for forming the electric field shielding layer. An antenna pattern and a first coil pattern are formed on a second layer L2 among the plurality of layers, while the first coil pattern is also formed on a third layer L3 among the plurality of layers. A third coil pattern is formed on a fourth layer L4 and a fifth layer L5 among the plurality of layers. A second coil pattern is formed on a sixth layer L6 among the plurality of layers. As depicted in FIG. 6A, d2-d6 represent the distances between the layers L2-L6 and the charging side CS, respectively, wherein d2<d3<d4<d5<d6. Also, the wireless charging printed circuit board 104 further includes a via VA1 (such as a buried via) which passes through the layers L2-L3 and a via VA2 (such as a buried via) which passes through the layers L4-L5 for providing flexible electrical connections between layers. The wireless charging printed circuit board 104 may further include a via VA3 (such as a buried via) which passes through the layers L2-L5 and/or a via VA4 (such as a buried via) which passes through the layers L2-L6 for reducing the DCR of the charging coils. Although not shown in FIG. 6A, the wireless charging printed circuit board 104 may also include a through via or a blind via for further reducing the DCR of the charging coils. The first coil patterns on the second layer L2 and the third layer L3 coupled in parallel by the via VA1 form a first primary charging coil, while the third coil patterns on the fourth layer L4 and the fifth layer L5 coupled in parallel by the via VA2 form a second primary charging coil. The second coil pattern on the sixth layer L6 forms an auxiliary charging coil.

In the wireless charging printed circuit board 204 depicted in FIG. 6B, an electric field shielding mechanism is implemented on a first layer L1 among the plurality of layers for forming the electric field shielding layer. A first coil pattern is formed on a second layer L2 among the plurality of layers. An antenna pattern and a second coil pattern is formed on a third layer L3 among the plurality of layers, while the second coil pattern is also formed on a fourth layer L4 among the plurality of layers. A third coil pattern is formed on a fifth layer L5 and a sixth layer L6 among the plurality of layers. As depicted in FIG. 6B, d2-d6 represent the distances between the layers L2-L6 and the charging side CS, respectively, wherein d2<d3<d4<d5<d6. Also, the wireless charging printed circuit board 204 further includes a via VA1 (such as a buried via) which passes through the layers L3-L4 and a via VA2 (such as a buried via) which passes through the layers L5-L6 for providing flexible electrical connections between layers. Although not shown in FIG. 6B, the wireless charging printed circuit board 204 may also include a through via or a blind via for further reducing the DCR of the charging coils. The first coil pattern on the second layer L2 forms a primary charging coil. The second coil patterns on the third layer L3 and the fourth layer L4 coupled in parallel by the via VA1 form a first auxiliary charging coil, while the third coil patterns on the fifth layer L5 and the sixth layer L6 coupled in parallel by the via VA2 form a second primary charging coil.

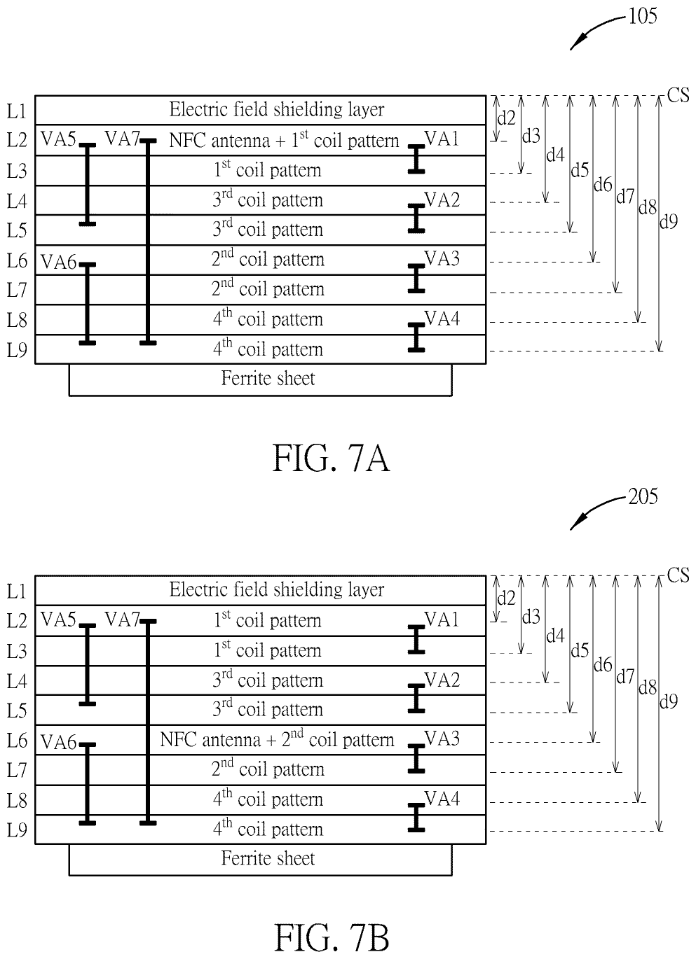

FIGS. 7A and 7B are schematic diagrams illustrating the implementation of the wireless charging printed circuit boards 100 and 200 which adopt multiple primary coils and multiple auxiliary coils in a stacked configuration according to embodiments of the present disclosure. FIG. 7A is a schematic diagram illustrating a wireless charging printed circuit board 105 implemented based on the wireless charging printed circuit board 100 depicted in FIG. 1. FIG. 7B is a schematic diagram illustrating a wireless charging printed circuit board 205 implemented based on the wireless charging printed circuit board 200 depicted in FIG. 2.

In the wireless charging printed circuit board 105 depicted in FIG. 7A, an electric field shielding mechanism is implemented on a first layer L1 among the plurality of layers for forming the electric field shielding layer. An antenna pattern and a first coil pattern are formed on a second layer L2 among the plurality of layers, while the first coil pattern is also formed on a third layer L3 among the plurality of layers. A third coil pattern is formed on a fourth layer L4 and a fifth layer L5 among the plurality of layers. A second coil pattern is formed on a sixth layer L6 and a seventh layer L7 among the plurality of layers. A fourth coil pattern is formed on an eighth layer L8 and a ninth layer L9 among the plurality of layers. As depicted in FIG. 7A, d2-d9 represent the distances between the layers L2-L9 and the charging side CS, respectively, wherein d2<d3<d4<d5<d6<d7<d8<d9. Also, the wireless charging printed circuit board 105 further includes a via VA1 (such as a buried via) which passes through the layers L2-L3, a via VA2 (such as a buried via) which passes through the layers L4-L5, a via VA3 (such as a buried via) which passes through the layers L6-L7, and a via VA4 (such as a buried via) which passes through the layers L8-L9 for providing flexible electrical connections between layers. The wireless charging printed circuit board 105 may further include a via VA5 (such as a buried via) which passes through the layers L2-L5, a via VA6 (such as a buried via) which passes through the layers L6-L9 and/or a via VA7 (such as a buried via) which passes through the layers L2-L9 for reducing the DCR of the charging coils. Although not shown in FIG. 7A, the wireless charging printed circuit board 105 may also include a through via or a blind via for further reducing the DCR of the charging coils. The first coil patterns on the second layer L2 and the third layer L3 coupled in parallel by the via VA1 form a first primary charging coil, while the third coil patterns on the fourth layer L4 and the fifth layer L5 coupled in parallel by the via VA2 form a second primary charging coil. The second coil patterns on the sixth layer L6 and the seventh layer L7 coupled in parallel by the via VA3 form a first auxiliary charging coil, while the fourth coil patterns on the eighth layer L8 and the ninth layer L9 coupled in parallel by the via VA4 form a second auxiliary charging coil.

In the wireless charging printed circuit board 205 depicted in FIG. 7B, an electric field shielding mechanism is implemented on a first layer L1 among the plurality of layers for forming the electric field shielding layer. A first coil pattern is formed on a second layer L2 and a third layer L3 among the plurality of layers. A third coil pattern is formed on a fourth layer L4 and a fifth layer L5 among the plurality of layers. An antenna pattern and a second coil pattern is formed on a sixth layer L6 among the plurality of layers, while the second coil pattern is also formed on a seventh layer L7 among the plurality of layers. A fourth coil pattern is formed on an eighth layer L8 and a ninth layer L9 among the plurality of layers. Also, the wireless charging printed circuit board 205 further includes a via VA1 (such as a buried via) which passes through the layers L2-L3, a via VA2 (such as a buried via) which passes through the layers L4-L5, a via VA3 (such as a buried via) which passes through the layers L6-L7, and a via VA4 (such as a buried via) which passes through the layers L8-L9 for providing flexible electrical connections between layers. The wireless charging printed circuit board 205 may further include a via VA5 (such as a buried via) which passes through the layers L2-L5, a via VA6 (such as a buried via) which passes through the layers L6-L9 and/or a via VA7 (such as a buried via) which passes through the layers L2-L9 for reducing the DCR of the charging coils. Although not shown in FIG. 7B, the wireless charging printed circuit board 105 may also include a through via or a blind via for further reducing the DCR of the charging coils. The first coil patterns on the second layer L2 and the third layer L3 coupled in parallel by the via VA1 form a first primary charging coil, while the third coil patterns on the fourth layer L4 and the fifth layer L5 coupled in parallel by the via VA2 form a second primary charging coil. The second coil patterns on the sixth layer L6 and the seventh layer L7 coupled in parallel by the via VA3 form a first auxiliary charging coil, while the fourth coil patterns on the eighth layer L8 and the ninth layer L9 coupled in parallel by the via VA4 form a second auxiliary charging coil.

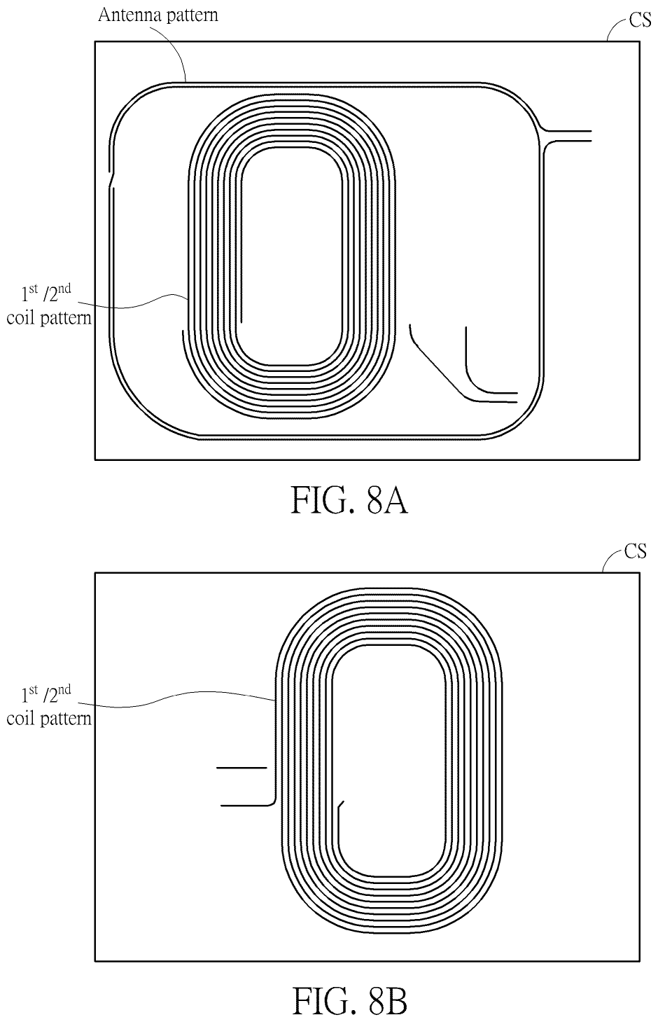

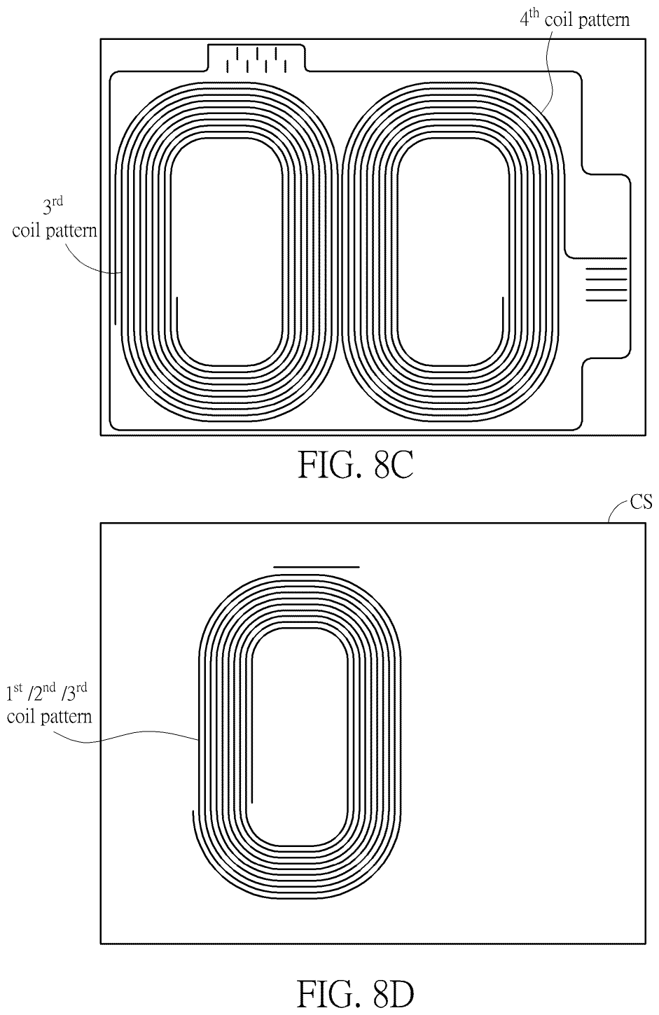

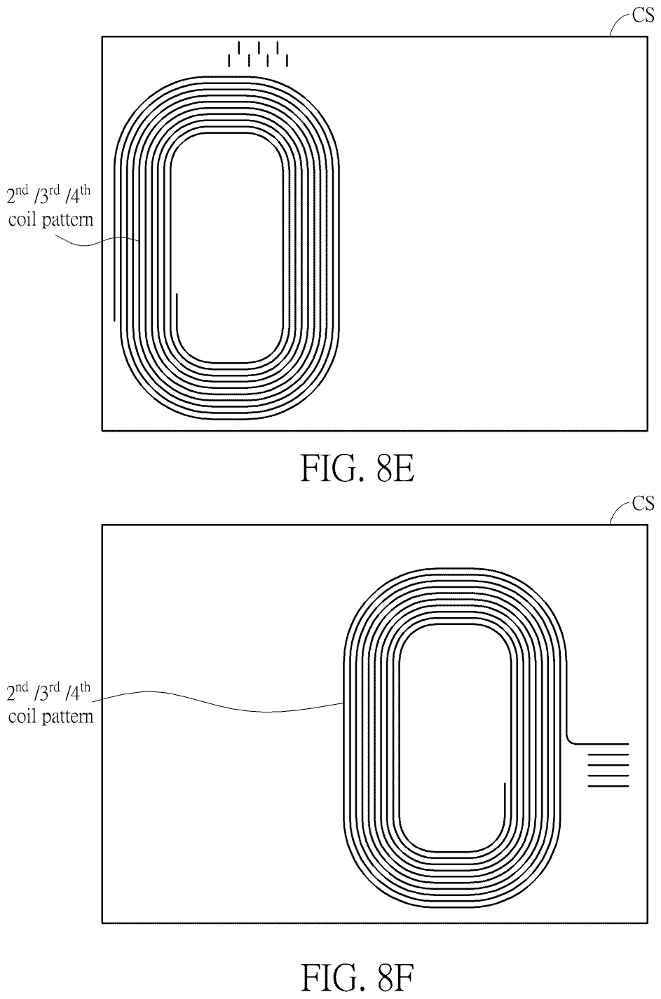

FIGS. 8A-8F are top-view schematic diagrams illustrating the wireless charging printed circuit board 100 or 200 according to embodiments of the present disclosure. Looking into the charging side CS of the wireless charging printed circuit board 101 of FIG. 3A, FIG. 8A depicts the top-view diagram of the second layer L2 which accommodates the antenna pattern and the first coil pattern, while FIG. 8B depicts the top-view diagram of the third layer L3 which accommodates the second coil pattern. Looking into the charging side CS of the wireless charging printed circuit board 201 of FIG. 3B, FIG. 8A depicts the top-view diagram of the third layer L3 which accommodates the antenna pattern and the second coil pattern, while FIG. 8B depicts the top-view diagram of the second layer L2 which accommodates the first coil pattern. In the present wireless charging printed circuit boards 101 and 201, the antenna pattern does not intersect the first coil pattern or the second coil pattern on the same layer.

Looking into the charging side CS of the wireless charging printed circuit board 102 of FIG. 4A, FIG. 8A depicts the top-view diagram of the second layer L2 which accommodates the antenna pattern and the first coil pattern, FIG. 8B depicts the top-view diagram of the third layer L3 which accommodates the second coil pattern, and FIG. 8C depicts the top-view diagram of the fourth layer L3 which accommodates the third coil pattern and the fourth coil pattern. Looking into the charging side CS of the wireless charging printed circuit board 202 of FIG. 4B, FIG. 8A depicts the top-view diagram of the third layer L3 which accommodates the antenna pattern and the second coil pattern, FIG. 8B depicts the top-view of the second layer L2 which accommodates the first coil pattern, and FIG. 8C depicts the top-view diagram of the fourth layer L3 which accommodates the third coil pattern and the fourth coil pattern.

Looking into the charging side CS of the wireless charging printed circuit board 103 of FIG. 5A, FIG. 8A depicts the top-view diagram of the second layer L2 which accommodates the antenna pattern and the first coil pattern, FIG. 8D depicts the top-view diagram of the third layer L3 which accommodates the first coil pattern, and FIG. 8B depicts the top-view diagram of the fourth layer L4 and the fifth layer L5 which accommodates the second coil pattern. Looking into the charging side CS of the wireless charging printed circuit board 203 of FIG. 5B, FIG. 8B depicts the top-view diagram of the second layer L2 and the third layer L3 which accommodate the first coil pattern, FIG. 8A depicts the top-view diagram of the fourth layer L4 which accommodates the antenna pattern and the second coil pattern, and FIG. 8D depicts the top-view diagram of the fifth layer L5 which accommodates the second coil pattern.

Looking into the charging side CS of the wireless charging printed circuit board 104 of FIG. 6A, FIG. 8A depicts the top-view diagram of the second layer L2 which accommodates the antenna pattern and the first coil pattern, FIG. 8D depicts the top-view of the third layer L3 which accommodates the first coil pattern, FIG. 8B depicts the top-view diagram of the fourth layer L4 and the fifth layer L5 which accommodate the third coil pattern, and FIG. 8E or 8F depicts the top-view diagram of the sixth layer L6 which accommodates the second coil pattern. Looking into the charging side CS of the wireless charging printed circuit board 204 of FIG. 6B, FIG. 8B depicts the top-view diagram of the second layer L2 which accommodates the first coil pattern, FIG. 8A depicts the top-view diagram of the third layer L3 which accommodates the antenna pattern and the second coil pattern, FIG. 8D depicts the top-view diagram of the fourth layer L4 which accommodates the second coil pattern, and FIG. 8E or 8F depicts the top-view diagram of the fifth layer L5 and the sixth layer L6 which accommodates the third coil pattern.

Looking into the charging side CS of the wireless charging printed circuit board 105 of FIG. 7A, FIG. 8A depicts the top-view diagram of the second layer L2 which accommodates the antenna pattern and the first coil pattern, FIG. 8D depicts the top-view diagram of the third layer L3 which accommodates the first coil pattern, FIG. 8B depicts the top-view diagram of the fourth layer L4 and the fifth layer L5 which accommodate the third coil pattern, FIG. 8E depicts the top-view diagram of the sixth layer L6 and the seventh layer L7 which accommodate the second coil pattern, and FIG. 8F depicts the top-view diagram of the eighth layer L8 and the ninth layer L9 which accommodate the fourth coil pattern. Looking into the charging side CS of the wireless charging printed circuit board 205 of FIG. 7B, FIG. 8B depicts the top-view diagram of the second layer L2 and the third layer L3 which accommodate the first coil pattern, FIG. 8D depicts the top-view diagram of the fourth layer L4 and the fifth layer L5 which accommodate the third coil pattern, FIG. 8A depicts the top-view diagram of the sixth layer L6 which accommodates the antenna pattern and the second coil pattern, FIG. 8D depicts the top-view of the seventh layer L7 which accommodates the second coil pattern, and FIG. 8E or 8F depicts the top-view diagram of the eighth layer L8 and the ninth layer L9 which accommodates the fourth coil pattern.

In the embodiments depicted in FIGS. 8A-8F, each coil pattern includes a spiral winding surrounding a central power transfer area. However, the layouts of the coil patterns do not limit the scope of the present disclosure.

Compared to coil windings in a conventional wireless charging board, the thickness of copper clad and isolation dielectric layers in the present wireless charging printed circuit board is negligibly small so that multiple PCB layers can be viewed as the same layer of a conventional wireless charging board, thereby providing high-efficiency wireless charging.

In conclusion, the present disclosure provides a multi-function charging printed circuit board by forming a short-range antenna and multiple charging coils on multiple layers, wherein the short-range antenna and at least one charging coil is integrated on a single layer. One or more temperature-detecting units may be disposed on the charging side of the present charging printed circuit board for effectively dissipating heat and avoiding over-temperature accidents. A ferrite sheet may be attached to the bottom side of the present wireless charging printed circuit board for improving the efficiency of wireless charging.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wireless charging printed circuit board, comprising:
a charging side;
a bottom side;
a plurality of layers arranged between the charging side and the bottom side;
an electric field shielding mechanism implemented on a first layer among the plurality of layers;
an antenna pattern and a first coil pattern formed on a second layer among the plurality of layers;
a second coil pattern formed on a third layer among the plurality of layers; and
a ferrite sheet attached to the bottom side of the wireless charging printed circuit board, wherein:
the first coil pattern is arranged on a central region of the second layer; and
the antenna is arranged on a peripheral region of the second layer.

2. The wireless charging printed circuit board of claim 1, wherein:
a distance between the second layer and the charging side is smaller than a distance between the third layer and the charging side;
the first coil pattern on the second layer forms a primary charging coil; and
the second coil pattern on the third layer forms an auxiliary charging coil.

3. The wireless charging printed circuit board of claim 1, wherein:
a distance between the third layer and the charging side is smaller than a distance between the second layer and the charging side;
the first coil pattern on the second layer forms an auxiliary charging coil; and
the second coil pattern on the third layer forms a primary charging coil.

4. The wireless charging printed circuit board of claim 1, further comprising:
a third coil pattern and a fourth coil pattern formed on a fourth layer among the plurality of layers, wherein:
a distance between the second layer and the charging side is smaller than a distance between the fourth layer and the charging side;
a distance between the third layer and the charging side is smaller than the distance between the fourth layer and the charging side;
the first coil pattern on the second layer forms a first charging coil;
the second coil pattern on the third layer forms a second charging coil;
the third coil pattern on the fourth layer forms a third charging coil; and
the fourth coil pattern on the fourth layer forms a fourth charging coil.

5. The wireless charging printed circuit board of claim 1, further comprising a first via formed between the second layer and a fourth layer among the plurality of layers, wherein:
the first coil pattern is further formed on the fourth layer;
the first coil pattern on the second layer and the first coil pattern on the fourth layer are coupled in parallel by the first via and form a first charging coil; and
a distance between the second layer and the charging side is smaller than a distance between the fourth layer and the charging side.

6. The wireless charging printed circuit board of claim 5, further comprising a second via formed between the third layer and a fifth layer among the plurality of layers, wherein:
the second coil pattern is further formed on the fifth layer;
the second coil pattern on the third layer and the second coil pattern on the fifth layer are coupled in parallel by the second via and form a second charging coil; and
a distance between the third layer and the charging side is smaller than a distance between the fifth layer and the charging side.

7. The wireless charging printed circuit board of claim 6, further comprising:
a third via which passes through the second layer, the third layer, the fourth layer and the fifth layer.

8. The wireless charging printed circuit board of claim 5, further comprising:
a third coil pattern formed on a fifth layer and a sixth layer among the plurality of layers;
a second via formed between the fifth layer and the sixth layer, wherein:
the third coil pattern on the fifth layer and the third coil pattern on the sixth layer are coupled in parallel by the second via and form a second charging coil;
the distance between the fourth layer and the charging side is smaller than a distance between the fifth layer and the charging side; and
the distance between the fifth layer and the charging side is smaller than a distance between the sixth layer and the charging side.

9. The wireless charging printed circuit board of claim 8, further comprising:
a third via which passes through the second layer, the fourth layer, the fifth layer and the sixth layer.

10. The wireless charging printed circuit board of claim 8, further comprising:
a fourth via which passes through the second layer, the third layer, the fourth layer, the fifth layer and the sixth layer.

11. The wireless charging printed circuit board of claim 1, further comprising:
a first via formed between the second layer and a fourth layer among the plurality of layers;
a second via formed between a fifth layer and a sixth layer among the plurality of layers;
a third via formed between the third layer and a seventh layer among the plurality of layers;
a fourth via formed between an eighth layer and a ninth layer among the plurality of layers;
a third coil pattern formed on the fifth layer and the sixth layer;
a fourth coil pattern formed on the eighth layer and the ninth layer, wherein:
the first coil pattern is further formed on the fourth layer;
the second coil pattern is further formed on the seventh layer;
the first coil pattern on the second layer and the first coil pattern on the fourth layer are coupled in parallel by the first via and form a first charging coil;
the third coil pattern on the fifth layer and the third coil pattern on the sixth layer are coupled in parallel by the second via and form a second charging coil;
the second coil pattern on the third layer and the second coil pattern on the seventh layer are coupled in parallel by the third via and form a third charging coil;
the fourth coil pattern on the eighth layer and the fourth coil pattern on the ninth layer are coupled in parallel by the fourth via and form a fourth charging coil;
a distance between the second layer and the charging side is smaller than a distance between the fourth layer and the charging side;
the distance between the fourth layer and the charging side is smaller than a distance between the fifth layer and the charging side;
the distance between the fifth layer and the charging side is smaller than a distance between the sixth layer and the charging side;
a distance between the third layer and the charging side is smaller than a distance between the seventh layer and the charging side;
the distance between the seventh layer and the charging side is smaller than a distance between the eighth layer and the charging side; and
the distance between the eighth layer and the charging side is smaller than a distance between the ninth layer and the charging side.

12. The wireless charging printed circuit board of claim 11, further comprising:
a fifth via which passes through the second layer, the fourth layer, the fifth layer and the sixth layer;
a sixth via which passes through the third layer, the seventh layer, the eighth layer and the ninth layer; and
a seventh via which passes through the second layer through the ninth layer.

13. The wireless charging printed circuit board of claim 11, further comprising:
a fifth via which passes through the third layer, the fourth layer, the fifth layer and the sixth layer;
a sixth via which passes through the second layer, the seventh layer, the eighth layer and the ninth layer; and
a seventh via which passes through the second layer through the ninth layer.

14. The wireless charging printed circuit board of claim 1, wherein:
a distance between the first layer and the charging side is smaller than a distance between the second layer and the charging side; and
the distance between the first layer and the charging side is smaller than a distance between the third layer and the charging side.

15. The wireless charging printed circuit board of claim 1, further comprising a plurality of negative temperature coefficient (NTC) thermistors disposed on the charging side.

16. The wireless charging printed circuit board of claim 1, further comprising:
a first via formed between the charging side and the charging side and passing through the plurality of layers.

17. The wireless charging printed circuit board of claim 16, further comprising:
a second via formed between the second layer and the third layer.

18. The wireless charging printed circuit board of claim 1, wherein the antenna pattern encircles the first coil pattern when looking into the second layer from the charging side.

19. The wireless charging printed circuit board of claim 1, wherein each coil pattern includes a spiral winding surrounding a power transfer area.

20. The wireless charging printed circuit board of claim 1, wherein the antenna pattern forms a near-field communication (NFC) antenna.
